(19) United States
(12) Patent Application Publication
(10) Pub. No.: US 2026/0361316 A1
(43) Pub. Date: Nov. 12, 2026

(54) Importance-Based Data Compression System

(71) Applicant: Jiwon Lee, Seongnam-si (KR)

(72) Inventor: Jiwon Lee, Seongnam-si (KR)

(21) Appl. No.: 19/645,114

(22) Filed: Apr. 11, 2026

(30) Foreign Application Priority Data
May 8, 2025 (KR) 10-2025-0060760

(51) Int. Cl. H03M 7/30

(52) U.S. Cl. CPC H03M 7/3079; H03M 7/6011

(57) ABSTRACT

A data compression system optimizes data storage efficiency through importance-based data classification. The system analyzes accumulated data in real-time for importance, repetitiveness, and redundancy, and a compression control unit monitors system state to determine optimal compression timing. Data is classified into four groups: an S group for core information that is fully preserved, an A group for important information that is summarized, a B group for auxiliary information that is compressed or deleted, and a C group for incidental information that is disposed of. A context restoration unit prevents contextual discontinuity by automatically generating linking information to maintain logical continuity between compressed data. The system achieves up to 40-60% reduction in memory usage while preserving the essential value of information through differential processing based on importance classification.

### CROSS-REFERENCE TO RELATED APPLICATIONS

This application claims priority to Korean Patent Application No. 10-2025-0060760, filed on May 9, 2025, the entire contents of which are incorporated herein by reference.

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ELECTRONICALLY

Not Applicable

### STATEMENT REGARDING PRIOR DISCLOSURES BY THE INVENTOR OR A JOINT INVENTOR

Not Applicable

### Background of the Invention

### Field of the Invention

The present invention relates generally to data compression systems in information processing environments, and more particularly to a system and method for optimizing data storage efficiency through importance-based data classification with context-preserving compression and dynamic adaptation capabilities.

### Description of the Related Art

Conventional information processing systems have experienced difficulties in efficient information management while continuously accumulating large amounts of data. Existing data management approaches fall largely into two categories.

First, a “preserve all information” approach unconditionally stores all data, thereby providing complete information accessibility, but causes system resource overload and memory inefficiency. In particular, as large amounts of data accumulate, problems such as system performance degradation, reduced search efficiency, and decreased processing speed become more severe.

Second, a “random deletion” approach arbitrarily deletes old data or data according to specific criteria to reduce system load, but has the problem that important information may be lost and continuity between information is broken, making data restoration difficult. This undermines information consistency and connectivity, and can lead to qualitative degradation of training data, particularly in AI systems.

Third, conventional data management systems lack differential processing mechanisms based on importance, treating all data with the same importance or processing based only on simple criteria such as time and frequency. In particular, mechanisms for effectively evaluating the semantic importance of data are insufficient, and the distinction between important and incidental information remains unclear. Furthermore, the capability to restore data when needed after data compression or summarization has been limited, making it difficult to achieve a balance between data processing efficiency and information value preservation.

A key deficiency of conventional compression techniques is the inability to preserve contextual connectivity during compression. When data is compressed or partially deleted, the logical relationships between remaining information elements are severed, creating contextual gaps that degrade the usability of restored data. Conventional compression algorithms focus exclusively on reducing data size without considering the semantic relationships between data elements, resulting in compressed datasets that lack coherent information flow even when individual elements are successfully restored.

Additionally, conventional data compression systems apply uniform compression strategies regardless of data importance. All data receives identical compression treatment, meaning that critical information undergoes the same aggressive compression as trivial data. This one-size-fits-all approach results in either insufficient compression (preserving too much low-value data) or excessive information loss (over-compressing high-value data).

Therefore, a data compression system is needed that: (1) intelligently evaluates data importance through multi-dimensional analysis; (2) applies differential compression strategies based on importance classification; (3) preserves contextual connectivity between compressed data elements; (4) dynamically adapts compression behavior to changing system conditions; and (5) continuously improves classification accuracy through adaptive learning. The present invention addresses these needs through an importance-based classification system with context-preserving compression technology.

### BRIEF SUMMARY OF THE INVENTION

The present invention provides a technical solution that improves the functioning of data storage systems by introducing an importance-based data compression system that achieves measurable improvements in memory utilization efficiency and data processing performance while preserving the essential value of information.

In accordance with one aspect of the invention, a data compression system comprises: an input unit for receiving data; a data analysis unit for analyzing data characteristics including importance, repetitiveness, and redundancy; a compression control unit for determining optimal compression timing; a priority classification unit for classifying data into importance-based groups; a group rule application unit for applying differential processing; a context restoration unit for maintaining contextual continuity; and a memory update unit for optimized storage management.

The system classifies data into S (Superior), A (Advanced), B (Basic), and C (Complementary) groups. S group data is fully preserved without compression, A group data undergoes summarization while maintaining essential information, B group data is subject to compression or deletion based on system conditions, and C group data is subject to immediate disposal. Each group receives differential treatment optimized for its importance level.

The core of the present invention is the S/A/B/C group classification system based on data importance. To effectively implement this system, the following supporting technical elements are employed: a data analysis mechanism that analyzes importance, repetitiveness, and redundancy in real-time to support accurate importance evaluation; a compression control algorithm that intelligently determines compression timing considering system memory usage, data accumulation volume, and processing load; a priority classification mechanism that comprehensively evaluates access frequency, most recent usage time, semantic importance, and association with other data to calculate importance scores; and a context restoration technology that automatically inserts linking information to prevent contextual discontinuity when restoring compressed data.

A key innovation of the present invention is the context restoration technology that addresses the fundamental technical problem of contextual disconnection in conventional compression systems. By utilizing intelligent analysis technology including natural language processing models, semantic analysis algorithms, and pattern matching systems, the system infers the context of compressed or deleted information and automatically generates linking context, thereby maintaining logical continuity of information even after aggressive compression operations.

The invention further incorporates an adaptive learning function that automatically adjusts group-specific processing rules based on previous processing results and user feedback, such that classification accuracy and context maintenance capability continuously improve as system usage accumulates.

Through this approach, the present invention achieves a concrete technical improvement by reducing system memory usage by up to 40-60% while preserving the essential value of information, improving data processing speed, and improving data storage efficiency across diverse industrial applications, reducing operational costs while enhancing overall system performance.

The invention is applicable across diverse domains including large language model (LLM) context management, cloud computing storage optimization, IoT sensor data management, and medical information systems. Other objects, features, and advantages of the present invention will become apparent from the following detailed description, the accompanying drawings, and the appended claims.

### BRIEF DESCRIPTION OF THE DRAWINGS

FIG. 1 is a block diagram illustrating the overall structure of a data compression system 100 according to an embodiment of the present invention, showing an input unit 110, a data analysis unit 120, a compression control unit 130, a priority classification unit 140, an S group preservation processing unit 150, an A group summary processing unit 160, a B group compression/deletion processing unit 170, a C group disposal processing unit 180, a context restoration unit 190, and a memory update unit 195.

FIG. 2 is a flowchart illustrating a data analysis and classification process according to an embodiment of the present invention, showing a start point 210, a data characteristic analysis step 220, a compression necessity determination step 230, an importance score calculation and group classification step 240, a group-specific processing rule application step 250, a context restoration condition analysis and restoration preparation step 260, an optimized storage and memory update step 270, and an end point 280.

FIG. 3 is a block diagram illustrating a customizable compression option user interface according to an embodiment of the present invention, showing a user profile unit 310, a compression intensity selection unit 320, a group customization setting unit 330, a summary effect preview unit 340, and a compression setting confirmation unit 350.

### DETAILED DESCRIPTION OF THE INVENTION

The following detailed description presents the invention through various aspects including system architecture, classification mechanisms, data analysis and compression control, context restoration, adaptive learning, and implementation considerations. The embodiments described hereinafter are illustrative examples to aid understanding of the present invention, and the scope of the invention is not limited thereto.

### 10.1 System Architecture Overview

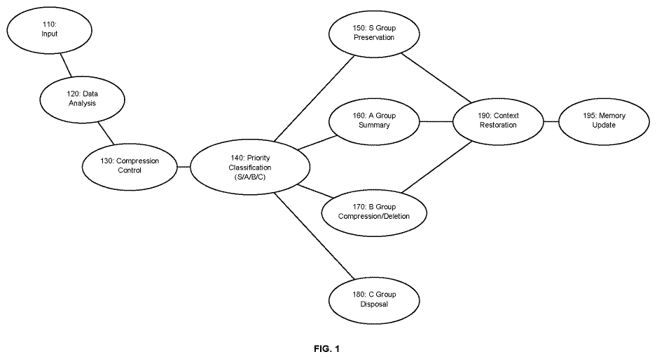

Referring to FIG. 1, a data compression system 100 according to an embodiment of the present invention comprises: an input unit 110; a data analysis unit 120; a compression control unit 130; a priority classification unit 140; group-specific processing units (150, 160, 170, 180) for differential treatment based on importance classification; a context restoration unit 190; and a memory update unit 195. These components operate in coordination to implement importance-based data compression with context preservation and adaptive learning capabilities, enabling efficient memory utilization while maintaining information value across diverse deployment domains.

The input unit 110 receives user input data and serves as the basic interface for the system. The input unit 110 performs basic format verification and preprocessing on received data, includes a data preprocessing module configured to assign processing priorities, and performs standardization processing for various data formats including text, structured data, and multimedia content. The preprocessing module pre-analyzes incoming data characteristics to expedite downstream analysis operations.

The data analysis unit 120 is a core module configured to analyze importance, repetitiveness, and redundancy of data in real-time. This unit implements multi-dimensional analysis using weighted scoring algorithms to produce quantitative importance assessments that enable precise classification decisions. The detailed operation of this unit is described in Section 10.3.

The compression control unit 130 monitors system state parameters to determine optimal timing for data compression operations. This component provides a technical improvement by intelligently determining when compression should occur based on real-time system conditions rather than using fixed schedules or manual triggers. Monitoring targets include system memory usage, amount of data being processed, and user activity patterns. For example, the compression process is activated when memory usage exceeds a set threshold (e.g., default value of 80%) or when data processing speed drops below a certain level.

The priority classification unit 140 classifies data into S/A/B/C groups based on results analyzed by the data analysis unit 120. The classification process utilizes quantified importance scores to assign each data element to the appropriate priority group, implementing both rule-based mechanisms for immediate effectiveness and learning-based mechanisms that progressively improve accuracy through pattern recognition. The detailed classification mechanism is described in Section 10.2.

The system implements four group-specific processing units that apply differential treatment strategies based on importance classification. The S group preservation processing unit 150 completely preserves core information without compression or deletion. The A group summary processing unit 160 applies intelligent summarization while maintaining content integrity, reducing storage requirements while preserving informational value. The B group compression/deletion processing unit 170 applies compression or selective deletion depending on capacity constraints and system conditions. The C group disposal processing unit 180 implements immediate removal of low-priority information.

The context restoration unit 190 restores compressed or deleted data while maintaining contextual continuity when the data is needed. This component addresses the fundamental technical problem of contextual disconnection that occurs in conventional compression technologies. The unit generates linking text and transition information to bridge gaps created by compression operations, ensuring that restored data maintains coherent information flow. The detailed operation of this unit is described in Section 10.4.

The memory update unit 195 stores and manages compressed data in an optimized form. The unit arranges group-processed data in efficient storage structures and places related data in physical proximity to improve access speed. Storage strategies balance compression ratio against access speed, while dynamic memory allocation maximizes space efficiency and automatic cleanup optimizes performance under varying system load.

These components operate in an integrated workflow: input flows through the input unit 110 to the data analysis unit 120 and compression control unit 130; the priority classification unit 140 classifies data and directs it to appropriate processing units (150-180); processed data passes through the context restoration unit 190 for contextual continuity preparation; and the memory update unit 195 stores processed data in optimized form. This architecture enables efficient data compression while maintaining information value across deployment domains.

### 10.2 S/A/B/C Classification Mechanism

The data compression system implements a hierarchical importance-based classification mechanism that assigns data to four distinct priority groups: S (Superior), A (Advanced), B (Basic), and C (Complementary). This classification framework enables differential compression treatment of data based on actual importance rather than simple temporal or frequency metrics, addressing the fundamental limitations of conventional uniform compression approaches.

The priority classification unit 140 evaluates data importance using multiple complementary criteria derived from data characteristic indicators: (1) access frequency measures how often data is accessed, including user interactions such as clicks, views, and edits; (2) most recent usage time evaluates recency of data access; (3) semantic importance analyzes the informational value and meaning of data content; and (4) association with other data assesses relationships and dependencies between data elements. These indicators are combined through weighted scoring to produce a quantified importance score for each data element.

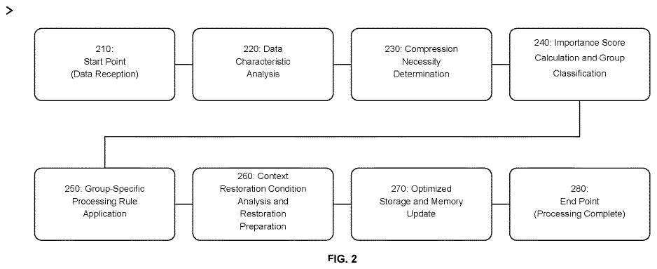

Based on these evaluation criteria, the priority classification unit assigns each data element an importance score and classifies it into one of the four priority groups. Referring to FIG. 2, the classification process proceeds as follows: data reception at start point 210; data characteristic analysis 220 analyzing importance, repetitiveness, and redundancy; compression necessity determination 230; importance score calculation and S/A/B/C group classification 240; group-specific processing rule application 250; context restoration condition analysis and restoration preparation 260; optimized storage and memory update 270; and processing completion 280.

S Group (Superior) contains core information that is fully maintained without deletion or compression. This includes data that forms the foundation of information processing within the system, key decision-making information, data serving as essential connection points for maintaining contextual flow, and data related to key user questions or commands, major system responses, and important decisions. For example, data with an information importance score of 0.85 or higher is automatically classified into the S group. S group data receives complete preservation with allocation to highest-priority storage.

A Group (Advanced) contains important information for which essential content is maintained while the expression method can be summarized concisely. This includes detailed data forming the background of key concepts or decisions, core details related to specific topics or projects, and data such as specific explanations, detailed examples, and extended analyses. For example, data with an importance score between 0.65 and 0.85 is classified into the A group. A group data undergoes summarization achieving approximately 20-30% size reduction while maintaining informational integrity.

B Group (Basic) contains auxiliary information that can be compressed, summarized, or partially deleted depending on circumstances and conditions. This includes supplementary data supporting core information, information that was important for a certain period but has decreased in importance over time, and supplementary explanations, repetitive expressions, and extended information. For example, data with an importance score between 0.35 and 0.65 is classified into the B group. B group data receives compression or deletion based on capacity requirements, achieving approximately 50-70% size reduction.

C Group (Complementary) contains incidental information that can be immediately disposed of for system performance optimization. This includes data with low potential for reuse after one-time use, incidental information with low relevance to core content, and formal greetings, repetitive confirmations, and unnecessary decorative expressions. For example, data with an importance score below 0.35 is classified into the C group. C group data is discarded immediately with 100% space recovery.

The differential processing strategies create a memory allocation hierarchy concentrating resources on high-value information. In typical deployments, S group data (representing approximately 10-15% of items) receives full preservation; A group data (approximately 20-25%) receives summarization; B group data (approximately 30-35%) receives compression or deletion; and C group data (approximately 30-35%) is completely discarded. These allocation ratios may vary depending on specific deployment requirements.

The system includes a group rule application unit that applies processing methods matching characteristics of each group. The group rule application unit includes an adaptive adjustment mechanism that dynamically adjusts processing criteria and processing intensity for each group according to system operating conditions including system load state, memory usage, user activity patterns, data characteristics, and user preferences. This dynamic adjustment capability represents a technical improvement over static compression approaches that apply fixed rules regardless of system state.

The group rule application unit further includes a data type recognition function that differentiates and applies processing methods of the S/A/B/C groups according to data types, and a learning mechanism that automatically adjusts processing rules for each group based on previous processing results and user feedback.

### 10.3 Data Analysis and Compression Control

The data analysis unit 120 implements three core analysis functions that provide the quantitative foundation for accurate S/A/B/C classification:
10.3.1 Importance Analysis Function: Input consists of received data and existing data within the system. The processing calculates importance using a weighted summation formula ((W1×frequency)+(W2×recency)+(W3×semantic importance)+(W4×association)) considering access frequency, most recent usage time, semantic importance, and association with other data. Output is an importance score in the range of 0 to 1. This quantitative scoring approach provides a concrete technical mechanism for evaluating data importance that goes beyond simple time-based or frequency-based methods used in conventional systems.
10.3.2 Repetitiveness Analysis Function: Input consists of new data and existing stored data. The processing detects repetition patterns through similarity measurement algorithms such as cosine similarity and Jaccard index. Output is a repetitiveness index in the range of 0 to 1. When data exhibits high repetitiveness, the system identifies the first instance for classification based on actual importance while subsequent repetitive instances are flagged for potential C group classification, preventing storage waste from redundant information.
10.3.3 Redundancy Analysis Function: Input consists of data to be analyzed. The processing analyzes redundancy through multiple dimensions: keyword redundancy analysis measures the frequency and distribution patterns of identical or similar key terms; content redundancy analysis evaluates content match through calculation of semantic similarity between sentences using cosine similarity and Jaccard index; structural redundancy analysis analyzes the match of formal patterns, paragraph structures, and information arrangement methods; and comprehensive evaluation calculates an integrated redundancy index by applying weights to each analysis result. Output is a redundancy index in the range of 0 to 1.

The compression control unit 130 implements intelligent timing determination for compression operations based on continuous system state monitoring. The unit monitors system condition parameters including system resource state indicators (memory usage, CPU utilization), data processing state indicators (data accumulation rate, processing queue depth), and user setting indicators (manual compression thresholds, priority preferences). For example, the compression process is activated when memory usage exceeds a set threshold (e.g., default value of 80%) or when data processing speed drops below a certain level. This intelligent timing approach ensures that compression operations occur at optimal moments, minimizing performance impact while preventing resource exhaustion.

The priority classification unit 140 implements a multi-step importance calculation process: Step 1 extracts data characteristic indicators including access frequency, most recent usage time, semantic importance, and association; Step 2 applies weights for each indicator and calculates a comprehensive score; Step 3 performs automatic group classification according to the importance score; and Step 4 transmits classification results to the group rule application unit. Here, access frequency includes user interaction patterns such as clicks, views, and edits.

In one embodiment, a comprehensive characteristic analysis structure of the priority classification unit improves upon limitations of conventional single-dimension characteristic processing models and comprises: a feature extraction layer configured to simultaneously extract multi-dimensional characteristics from input data; a parallel processing layer configured to independently process the extracted characteristics; a weight optimization layer configured to automatically adjust importance of each characteristic according to data context; and an integrated analysis layer configured to synthesize the weighted characteristics to calculate a final importance score, thereby enabling more accurate importance evaluation than conventional classification models through integrated analysis of diverse data characteristics.

### 10.4 Context Restoration and Continuity Preservation

The context restoration unit 190 performs operations to maintain logical flow and contextual coherence when compressed or deleted information requires restoration. This mechanism ensures that aggressive data compression does not result in discontinuities or contextual gaps, addressing the fundamental technical problem of information disconnection in conventional compression systems. This represents a key innovation of the present invention that distinguishes it from conventional compression technologies.

The context restoration unit 190 restores compressed or deleted data while maintaining contextual continuity when the data is needed. The restoration condition analysis process operates as follows: input consists of compression-processed data and restoration request information; processing analyzes restoration possibility and determines restoration priority; and output determines restoration target data and restoration method.

The data restoration execution utilizes intelligent analysis technology such as artificial intelligence models, machine learning algorithms, and rule-based inference systems. Based on metadata and keyword information stored during compression, the system infers original information of compressed data and restores it while maintaining contextual continuity. Restored data is verified for consistency with the original to ensure quality.

In one embodiment, the context restoration unit 190 maintains contextual connectivity between compression-processed information through a four-step process:
Step 1—Context Information Extraction: Extracts key keywords, topic flow, and logical connection points from data before and after compression and stores the extracted information as context information. This step captures the semantic structure of information relationships prior to compression, creating a restoration map that guides subsequent reconnection operations.
Step 2—Connectivity Analysis: Analyzes semantic relevance and temporal order between compressed information blocks based on the compressed information blocks and the context information to determine connection priority. The analysis identifies which information blocks require linking and establishes the priority order for reconnection based on semantic distance and logical dependency.
Step 3—Context Linking Text Generation: Automatically generates concise linking text for natural connection between information blocks by utilizing a connection relationship matrix and the compressed information blocks. The generated linking text bridges contextual gaps created by compression, enabling coherent information flow across compressed data boundaries.
Step 4—Linking Text Optimization: Verifies and optimizes quality of the generated linking text through a semantic consistency score. This verification ensures that the generated linking text accurately represents the original contextual relationships and maintains semantic coherence with surrounding information blocks.

This four-step context restoration process effectively maintains contextual continuity between compressed information, solving the fundamental problem of information disconnection that plagues conventional compression technologies. The approach enables aggressive compression while preserving the logical relationships essential for meaningful data utilization.

The system implements differential restoration strategies based on group classification: S group data receives complete restoration with full contextual reconstruction; A group data is restored with summary information and contextual linking; B group data undergoes selective restoration based on relevance to current requirements; and C group data is skipped in restoration operations. This differential approach ensures that restoration resources are concentrated on high-value information while maintaining efficient resource utilization.

### 10.5 Adaptive Learning and Continuous Improvement

The present invention implements an adaptive learning function that evolves over time through accumulated operational experience, enabling the system to continuously improve classification accuracy and compression effectiveness. This learning capability provides ongoing technical improvement in system performance.

The adaptive learning function collects user feedback and system performance data, automatically adjusts weights of the priority classification unit, and dynamically optimizes S/A/B/C group classification thresholds. As system usage accumulates, classification accuracy and context maintenance capability continuously improve.

The learning mechanism operates through feedback integration: classification decisions are compared against actual data access patterns to evaluate classification accuracy; weight adjustments are applied to the importance calculation formula based on observed patterns; group boundary thresholds are dynamically optimized based on actual data distribution and access characteristics; and compression parameters are refined based on restoration quality metrics.

The group rule application unit includes a learning mechanism that automatically adjusts processing rules for each group based on previous processing results and user feedback. When users provide feedback on compression results or when system performance metrics indicate suboptimal compression decisions, the learning mechanism incorporates this information to refine future processing rules.

The adaptive adjustment mechanism dynamically adjusts group-specific processing criteria according to system operating conditions. Under high memory pressure, the system may apply more aggressive compression to B group data and expand C group classification criteria. Under low memory pressure, the system may apply lighter compression and promote borderline data to higher-priority groups. This dynamic behavior ensures optimal performance across varying operational conditions.

### 10.6 Computational Efficiency of Four-Tier Classification

The four-tier classification structure (S/A/B/C groups) provides computational efficiency due to alignment with binary computer architecture. The four priority groups can be represented using exactly 2 bits of storage (2²=4 possible values), enabling efficient encoding and processing. This power-of-two structure enables fast priority determination operations and efficient memory utilization.

The four-tier structure also provides a balance between practical usability and technical efficiency. Four priority levels provide sufficient differentiation without excessive complexity. The classification aligns with intuitive importance distinctions: “essential” (S group), “important” (A group), “supplementary” (B group), and “transient” (C group). This structure facilitates classification operations while enabling efficient implementation.

### 10.7 Embodiment 1: LLM Context Management System

### 10.7.1 System Configuration

In this exemplary embodiment, the data compression system is deployed in a large language model (LLM) context management environment that manages extended conversation sessions with token limitations. The system addresses the challenge of maintaining relevant conversational context within limited context windows while ensuring response quality and coherence.

### 10.7.2 Classification Distribution

The priority classification unit 140 classifies conversation data based on contextual importance characteristics. For example, in one deployment: S group (approximately 15%) includes user-stated objectives and requirements, critical decision points, explicitly requested information retention, and foundational project context; A group (approximately 20%) includes recent conversation exchanges, user preferences and patterns, technical specifications, and actively referenced information; B group (approximately 30%) includes supporting details, resolved sub-topics, and general conversational context beyond immediate relevance; and C group (approximately 35%) includes acknowledgments, confirmations, off-topic content, and repetitive information. These distribution percentages are exemplary and may vary based on specific conversation patterns and user requirements.

### 10.7.3 Memory Savings Calculation

Applying differential processing strategies to the above distribution, memory savings are calculated as follows:

| | | Processing | | |
|---|---|---|---|---|
| Group | Population | Strategy | Calculation | Savings |
| S Group | 15% | Full | 15% × 0% | 0% |
| | | preservation | | |
| A Group | 20% | 20-30% | 20% × 25% | 5% |
| | | compression | | |
| B Group | 30% | 50-70% | 30% × 60% | 18% |
| | | compression | | |
| C Group | 35% | Complete | 35% × 100% | 35% |
| | | discard | | |
| Total | 100% | | | 58% |

With aggressive B group compression (70%), total memory savings reach: B group contribution: 30%×70%=21%; Total: 0%+5%+21%+35%=61%. In highly optimized deployments with maximum compression rates (A: 30%, B: 70%), memory savings can reach approximately 62%.

In LLM environments, these memory savings translate directly to context window token efficiency improvements of 40-60%, enabling the system to maintain more relevant context within fixed token limits. The context restoration algorithm maintains coherence of core information during long-text processing while achieving efficient compression, significantly reducing inference costs.

### 10.7.4 Summary

This embodiment demonstrates the invention applied to LLM context management: conversation elements are distributed into S/A/B/C groups based on contextual importance; critical context is preserved while acknowledgments and repetitive content are discarded; calculated memory savings are approximately 58-62%; and the context restoration unit maintains logical continuity between compressed conversation segments.

### 10.8 Embodiment 2: Cloud Storage Optimization System

### 10.8.1 System Configuration

In this exemplary embodiment, the data compression system is deployed in a cloud computing storage environment managing enterprise data. The system applies S/A/B/C classification to stored documents and data objects, reducing storage costs while maintaining data availability for critical operations.

### 10.8.2 Classification Distribution

The priority classification unit 140 classifies cloud storage entries based on business criticality and access patterns. For example, in one deployment: S group (approximately 10%) includes active project documents, compliance-required records, customer-facing data, and real-time operational data; A group (approximately 25%) includes recent reports, user collaboration files, and active reference materials; B group (approximately 35%) includes archived project files, historical reports, and infrequently-accessed reference data; and C group (approximately 30%) includes expired temporary files, superseded document versions, abandoned drafts, and outdated cache entries. These distribution percentages are exemplary and may vary based on specific enterprise workloads.

### 10.8.3 Memory Savings Calculation

Applying differential processing strategies to the above distribution, memory savings are calculated as follows:

| | | Processing | | |
|---|---|---|---|---|
| Group | Population | Strategy | Calculation | Savings |
| S Group | 10% | Full | 10% × 0% | 0% |
| | | preservation | | |
| A Group | 25% | 20-30% | 25% × 25% | 6.25% |
| | | compression | | |
| B Group | 35% | 50-70% | 35% × 60% | 21% |
| | | compression | | |
| C Group | 30% | Complete | 30% × 100% | 30% |
| | | discard | | |
| Total | 100% | | | 57.25% |

With aggressive B group compression (70%), total memory savings reach: B group contribution: 35%×70%=24.5%; Total: 0%+6.25%+24.5%+30%=60.75%. In highly optimized deployments, memory savings can reach approximately 62%.

### 10.8.4 Summary

This embodiment demonstrates the invention applied to cloud storage: enterprise data is distributed into S/A/B/C groups based on business criticality; compliance and operational data is preserved while expired temporary files are discarded; calculated memory savings are approximately 57-62%; and memory savings result in a direct reduction of cloud storage costs.

### 10.9 Embodiment 3: IoT Sensor Data Management System

### 10.9.1 System Configuration

In this exemplary embodiment, the data compression system is deployed in an IoT environment managing continuous sensor data streams. The system applies S/A/B/C classification to optimize data transmission volume and edge device storage while ensuring critical sensor readings are preserved for operational decisions.

### 10.9.2 Classification Distribution

The priority classification unit 140 classifies IoT sensor data based on operational significance. For example, in one deployment: S group (approximately 10%) includes anomaly detection alerts, safety threshold violations, and critical equipment status changes; A group (approximately 20%) includes trend-significant readings, calibration data, and periodic summary statistics; B group (approximately 30%) includes routine sensor readings within normal ranges and redundant periodic measurements; and C group (approximately 40%) includes duplicate readings, sensor noise, heartbeat signals, and routine status confirmations. These distribution percentages are exemplary and may vary based on specific IoT deployment characteristics.

### 10.9.3 Memory Savings Calculation

Applying differential processing strategies to the above distribution, memory savings are calculated as follows:

| | | Processing | | |
|---|---|---|---|---|
| Group | Population | Strategy | Calculation | Savings |
| S Group | 10% | Full | 10% × 0% | 0% |
| | | preservation | | |
| A Group | 20% | 20-30% | 20% × 25% | 5% |
| | | compression | | |
| B Group | 30% | 50-70% | 30% × 60% | 18% |
| | | compression | | |
| C Group | 40% | Complete | 40% × 100% | 40% |
| | | discard | | |
| Total | 100% | | | 63% |

With aggressive B group compression (70%), total memory savings reach: B group contribution: 30%×70%=21%; Total: 0%+5%+21%+40%=66%. In highly optimized deployments, memory savings can reach approximately 67%. Note: IoT deployments typically show higher memory savings (approximately 63-67%) due to aggressive C group allocation for routine sensor data.

### 10.9.4 Summary

This embodiment demonstrates the invention applied to IoT sensor data: sensor data is distributed into S/A/B/C groups based on operational significance; anomaly alerts are preserved while routine heartbeat signals are discarded; calculated memory savings are approximately 63-67%; and reduction in data transmission volume proportional to compression reduces bandwidth costs.

### 10.10 Embodiment 4: Medical Information System

### 10.10.1 System Configuration

In this exemplary embodiment, the data compression system is deployed in a medical information system managing patient records and clinical data. The system applies S/A/B/C classification to optimize storage while ensuring absolute preservation of safety-critical medical data.

### 10.10.2 Classification Distribution

The priority classification unit 140 classifies medical data based on clinical criticality. For example, in one deployment: S group (approximately 20%, higher than other embodiments due to patient safety requirements) includes active medications, allergy records, current diagnoses, critical lab results, and surgical history; A group (approximately 25%) includes recent visit notes, treatment plans, imaging reports, and specialist consultations; B group (approximately 30%) includes historical visit records, resolved conditions, routine lab history, and administrative correspondence; and C group (approximately 25%, lower than other embodiments due to the need to retain potentially relevant clinical data) includes expired appointment reminders, superseded insurance information, duplicate form submissions, and outdated notification logs. These distribution percentages are exemplary and may vary based on specific medical facility requirements and regulatory constraints.

### 10.10.3 Memory Savings Calculation

Applying differential processing strategies to the above distribution, memory savings are calculated as follows:

| | | Processing | | |
|---|---|---|---|---|
| Group | Population | Strategy | Calculation | Savings |
| S Group | 20% | Full | 20% × 0% | 0% |
| | | preservation | | |
| A Group | 25% | 20-30% | 25% × 25% | 6.25% |
| | | compression | | |
| B Group | 30% | 50-70% | 30% × 60% | 18% |
| | | compression | | |
| C Group | 25% | Complete | 25% × 100% | 25% |
| | | discard | | |
| Total | 100% | | | 49.25% |

With aggressive B group compression (70%), total memory savings reach: B group contribution: 30%×70%=21%; Total: 0%+6.25%+21%+25%=52.25%. In highly optimized deployments, memory savings can reach approximately 54%. Note: Medical deployments typically show lower memory savings (approximately 49-54%) compared to other embodiments due to the higher S group allocation required for patient safety data integrity.

### 10.10.4 Summary

This embodiment demonstrates the invention applied to medical information systems: medical data is distributed into S/A/B/C groups based on clinical criticality; safety-critical patient data is absolutely preserved while expired administrative data is discarded; calculated memory savings are approximately 49-54%; and the context restoration unit ensures clinical continuity when accessing compressed historical records.

### 10.11 Comparative Analysis of Embodiments

The four embodiments demonstrate the versatility and consistent effectiveness of the importance-based data compression system across diverse application domains. While implementation details vary according to domain-specific requirements, all embodiments share fundamental characteristics: S/A/B/C classification based on importance rather than simple criteria, differential compression based on group assignment, context restoration for maintaining information continuity, and systematic calculation methodology for performance estimation.

### 10.11.1 Cross-Domain Performance Comparison

Memory savings calculations show consistency across all deployment scenarios while reflecting domain-specific characteristics:

| | | | Memory | Key |
|---|---|---|---|---|
| Embodiment | S Group | C Group | Savings | Characteristic |
| LLM | 15% | 35% | approx. | Baseline |
| Context (10.7) | | | 58-62% | distribution |
| Cloud | 10% | 30% | approx. | Enterprise |
| Storage (10.8) | | | 57-62% | data emphasis |
| IoT | 10% | 40% | approx. | Aggressive sensor |
| Sensor (10.9) | | | 63-67% | optimization |
| Medical | 20% | 25% | approx. | Patient |
| System (10.10) | | | 49-54% | safety priority |

The variation in memory savings across embodiments directly reflects each domain's S/A/B/C group distribution requirements: LLM context management achieves approximately 58-62% savings using baseline distribution; cloud storage systems maintain substantial C group allocation for expired temporary files; IoT deployments maximize C group allocation (40%) for routine sensor data, achieving the highest savings (approximately 63-67%); and medical systems require higher S group allocation (20%) for patient safety, resulting in lower overall savings (approximately 49-54%).

### 10.11.2 Calculation Methodology Consistency

All embodiments apply the same calculation methodology:

Memory Savings Formula: Total Savings=Sum of (Group Population×Processing Rate)
Where:
S Group: 0% processing (full preservation)
A Group: 20-30% compression
B Group: 50-70% compression
C Group: 100% discard

This consistent methodology enables systematic performance estimation across diverse deployment scenarios while allowing for domain-specific parameter adjustments.

### 10.11.3 Advantages Over Traditional Approaches

All embodiments address the fundamental limitation of uniform compression: applying identical compression treatment regardless of data importance cannot optimize the trade-off between storage efficiency and information value preservation.

LLM Context Management: Critical user objectives (S Group) remain accessible throughout extended sessions regardless of token limitations, while acknowledgments and repetitive content (C Group) are immediately discarded to maximize available context window.

Cloud Storage: Compliance-required records and operational data (S Group) receive guaranteed preservation, while expired temporary files and abandoned drafts (C Group) are removed to reduce storage costs.

IoT Sensor Data: Anomaly alerts and safety threshold violations (S Group) receive absolute protection from compression, while routine heartbeat signals and sensor noise (C Group) are aggressively discarded to conserve edge device resources and transmission bandwidth.

Medical Information Systems: Active medications and allergy records (S Group) receive guaranteed preservation for patient safety, while expired appointment reminders and duplicate forms (C Group) are removed to optimize storage while maintaining clinical data integrity.

The four embodiments demonstrate that the same S/A/B/C classification framework provides consistent benefits across diverse applications through domain-specific distribution parameter adjustments. In particular, the context restoration technology provides value across all domains by maintaining information continuity even after aggressive compression, solving the fundamental problem of contextual disconnection in conventional compression approaches.

### 10.12 Adaptive User Interface

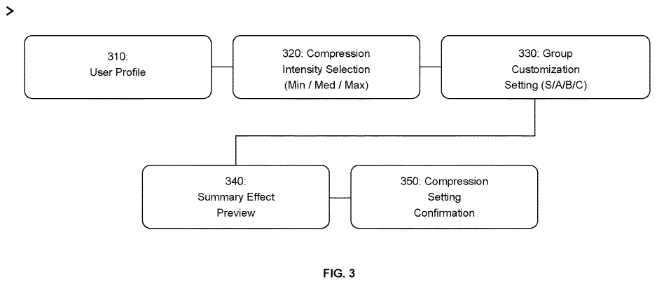

Referring to FIG. 3, the system includes an adaptive user interface that enables user customization of compression behavior. The user interface comprises: a user profile unit 310 for confirming personal setting information; a compression intensity selection unit 320 for selecting from minimum, medium, and maximum compression levels; a group customization setting unit 330 for adjusting S/A/B/C group processing methods to meet user needs; a summary effect preview unit 340 for confirming results of setting changes in real-time; and a compression setting confirmation unit 350 for completing all settings.

The adaptive user interface dynamically adjusts compression intensity according to system conditions, providing users with transparent control over the compression process while enabling the system to optimize automatically when user preferences are not explicitly specified.

### DESCRIPTION OF REFERENCE NUMERALS

### FIG. 1: Overall Structure of Data Compression System

110: Input
120: Data Analysis
130: Compression Control
140: Priority Classification (S/A/B/C)
150: S Group Preservation
160: A Group Summary
170: B Group Compression/Deletion
180: C Group Disposal
190: Context Restoration
195: Memory Update

### FIG. 2: Data Analysis and Classification Flow

210: Start Point (Data Reception)
220: Data Characteristic Analysis
230: Compression Necessity Determination
240: Importance Score Calculation and Group Classification
250: Group-Specific Processing Rule Application
260: Context Restoration Condition Analysis and Restoration Preparation
270: Optimized Storage and Memory Update
280: End Point (Processing Complete)

### FIG. 3: Customizable Compression Option UI Overview

310: User Profile
320: Compression Intensity Selection
330: Group Customization Setting
340: Summary Effect Preview
350: Compression Setting Confirmation

What is claimed is:

1. A data compression system for classifying and processing data according to information importance, the system comprising:
an input unit configured to receive user input data;
a data analysis unit configured to analyze importance, repetitiveness, and redundancy of data;
a compression control unit configured to monitor system state and determine timing for data compression;
a priority classification unit configured to classify data into groups based on the importance analyzed by the data analysis unit, the groups comprising:
an S group for core information that is fully maintained without deletion or compression,
an A group for important information that is summarizable while maintaining essential information,
a B group for auxiliary information that is maintained according to compression or deletion conditions, and
a C group for incidental information subject to immediate disposal;
a group rule application unit configured to apply processing methods matching characteristics of each group;
a context restoration unit configured to restore compressed or deleted data while maintaining contextual continuity when the data is needed; and
a memory update unit configured to store and manage compressed data in an optimized form.

2. The data compression system of claim 1, wherein the input unit includes a data preprocessing module configured to pre-analyze received data and assign processing priorities.

3. The data compression system of claim 1, wherein the compression control unit is configured to determine a compression initiation timing based on system condition parameters, and the system condition parameters include at least one of a system resource state indicator, a data processing state indicator, and a user setting indicator.

4. The data compression system of claim 1, wherein the priority classification unit is configured to analyze data characteristic indicators to quantify importance of data and classify the data into the S/A/B/C groups according to the quantified importance, and the data characteristic indicators include at least one of access frequency of the data, most recent usage time, semantic importance, and association with other data.

5. The data compression system of claim 1, wherein the group rule application unit includes an adaptive adjustment mechanism configured to dynamically adjust processing criteria and processing intensity for each group according to system operating conditions, and the system operating conditions include at least one of system load state, memory usage, user activity pattern, data characteristics, and user preferences.

6. The data compression system of claim 1, wherein the group rule application unit includes a data type recognition function configured to differentiate and apply processing methods of the S/A/B/C groups according to data types.

7. The data compression system of claim 1, wherein the group rule application unit includes a learning mechanism configured to automatically adjust processing rules for each group based on previous processing results and user feedback.

8. The data compression system of claim 1, wherein the context restoration unit includes an intelligent restoration function configured to analyze restoration conditions of compressed data and restore the compressed data while maintaining contextual continuity by utilizing intelligent analysis technology, and the intelligent analysis technology includes at least one of an artificial intelligence model, a machine learning algorithm, and a rule-based inference system.

9. The data compression system of claim 1, further comprising an adaptive user interface, wherein the adaptive user interface provides at least one of a user profile, a compression intensity selection, a group customization setting, a summary effect preview, and a compression setting confirmation function, and the adaptive user interface is configured to dynamically adjust compression intensity according to system conditions.

10. The data compression system of claim 1, further comprising an adaptive learning function configured to continuously improve classification performance based on user feedback and system performance data, wherein the adaptive learning function automatically adjusts weights of the priority classification unit and dynamically optimizes S/A/B/C group classification thresholds to improve classification accuracy.

11. The data compression system of claim 1, wherein a comprehensive characteristic analysis structure of the priority classification unit improves upon limitations of conventional single-dimension characteristic processing models and comprises:
a feature extraction layer configured to simultaneously extract multi-dimensional characteristics from input data;
a parallel processing layer configured to independently process the extracted characteristics;
a weight optimization layer configured to automatically adjust importance of each characteristic according to data context; and
an integrated analysis layer configured to synthesize the weighted characteristics to calculate a final importance score,
thereby enabling more accurate importance evaluation than conventional classification models through integrated analysis of diverse data characteristics.

12. The data compression system of claim 1, wherein the context restoration unit maintains contextual connectivity between compression-processed information through:
a context information extraction step of extracting key keywords, topic flow, and logical connection points from data before and after compression and storing the extracted information as context information;
a connectivity analysis step of analyzing semantic relevance and temporal order between compressed information blocks based on the compressed information blocks and the context information to determine connection priority;
a context linking text generation step of automatically generating concise linking text for natural connection between information blocks by utilizing a connection relationship matrix and the compressed information blocks; and
a linking text optimization step of verifying and optimizing quality of the generated linking text through a semantic consistency score,
thereby effectively maintaining contextual continuity between compressed information.

13. A method for data importance analysis and compression using the data compression system of any one of claim 1 to 12, the method comprising:
receiving input data;
analyzing importance of the received input data in real-time;
classifying the data into S/A/B/C groups according to importance based on results of the analysis;
differentially processing the data according to rules for each classified group; and
integrating the processed data to generate a final output.
